(19) United States
(12) Patent Application Publication
(10) Pub. No.: US 2013/0164461 A1
(43) Pub. Date: Jun. 27, 2013

(54) POSITIVE PHOTOSENSITIVE RESIN COMPOSITION AND USES THEREOF

(71) Applicant: CHI MEI CORPORATION, Tainan City (TW)

(72) Inventors: KAI-MIN CHEN, TAINAN CITY (TW); CHUN-AN SHIH, TAINAN CITY (TW)

(73) Assignee: CHI MEI CORPORATION, TAINAN CITY (TW)

(21) Appl. No.: 13/710,798

(22) Filed: Dec. 11, 2012

(30) Foreign Application Priority Data
Dec. 22, 2011 (TW) 100147873

(51) Int. Cl. G03F 7/039; G02F 1/1333

(52) U.S. Cl. CPC G03F 7/039; G02F 1/1333
USPC 428/1.6; 430/286.1; 430/319; 257/618

(57) ABSTRACT

The invention relates to a positive photosensitive resin composition with good temporal stability. The invention also provides a method for manufacturing a thin-film transistor array substrate, a thin-film transistor array substrate and a liquid crystal display device.

### BACKGROUND OF THE INVENTION

1. Field of the Invention

The invention relates to a positive photosensitive resin composition. Particularly, the invention relates to a positive photosensitive resin composition with good temporal stability and uses thereof.

2. Description of the Related Art

Recently, the semiconductor industry and liquid crystal display (LCD) device industry make the remarkable progress, the demand for personal computers and LCD continuously increases and the related technologies have a drastic advance, resulting in the higher resolution requirement. For satisfying those demands, a high-ortho novolac resin and a photosensitizer are typically added into the positive photosensitive resin composition, such as Japanese Patent Publication No. 2009-192571.

During the processes of the semiconductor integrated circuit device, the thin-film transistor of LCD or touch panel, the usage of the photosensitizer in the positive photosensitive resin composition is usually adjusted to reach higher exposure latitude; however, such photosensitive resin composition often causes the problem of temporal instability.

Accordingly, it is necessary to provide a positive photosensitive resin composition for improving shortcomings of lower resolution and temporal instability of the prior positive photosensitive resin composition.

### SUMMARY OF THE INVENTION

The invention relates to a positive photosensitive resin composition having an excellent formula and has an advantage of good temporal stability.

Therefore, the invention relates to a positive photosensitive resin composition comprising:
a novolac resin (A);
an ortho-naphthoquinone diazide sulfonic acid ester (B);
a dye (C); and
a solvent (D);
wherein the dye (C) comprises a dye (C-1) and a dye (C-2), and the dye (C-1) is selected from the group consisting of a disazo dye, an anthraquinone dye, and a trivalent chromium azo dye; and the dye (C-2) is a triarylmethane dye.

The present invention also provides a method for manufacturing a thin-film transistor array substrate. The thin-film transistor array substrate comprises a substrate and a pattern. The method comprises coating the positive photosensitive resin composition as mentioned above on the substrate to form the pattern.

The present invention also provides a thin-film transistor array substrate manufactured according to the method as mentioned above.

The present invention also provides a liquid crystal display device comprising the thin-film transistor array substrate as mentioned above.

### BRIEF DESCRIPTION OF THE DRAWINGS

FIG. 1 is a partial cross-sectional diagram of a TFT array substrate for a LCD device according to the present invention.

### DETAILED DESCRIPTION OF THE INVENTION

The invention relates to a positive photosensitive resin composition comprising:
a novolac resin (A);
an ortho-naphthoquinone diazide sulfonic acid ester (B);
a dye (C); and
a solvent (D);
wherein the dye (C) comprises a dye (C-1) and a dye (C-2), and the dye (C-1) is selected from the group consisting of a disazo dye, an anthraquinone dye, and a trivalent chromium azo dye; and the dye (C-2) is a triarylmethane dye.

The novolac resin (A) according to the invention refers to a resin typically obtained by condensing an aromatic hydroxyl compound with an aldehyde in the presence of a catalyst of a conventional organic acid and/or inorganic acid (such as hydrochloric acid, sulfuric acid, formic acid, acetic acid, oxalic acid, p-toluenesulfonic) followed by dehydration under the reduced pressure, and unreactive monomers are removed.

Examples of the aromatic hydroxyl compound include but are not limited to cresols such as phenol, m-cresol, p-cresol, o-cresol and the like; xylenols such as 2,3-dimethylphenol, 2,5-dimethylphenol, 3,5-dimethylphenol, 3,4-dimethylphenol and the like; alkyl phenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-cresol, 2-tert-butyl-5-cresol, 6-tert-butyl-3-cresol and the like; alkoxy phenols such as p-methoxyphenol, m-methoxyphenol, p-ethoxyphenol, m-ethoxyphenol, p-propoxyphenol, m-propoxyphenol and the like; isopropenyl phenols such as o-isopropenyl phenol, p-isopropenyl phenol, 2-methyl-4-isopropenyl phenol, 2-ethyl-4-isopropenyl phenol and the like; aryl phenols such as phenyl phenol; and polyhydroxyphenols such as 4,4′-dihydroxybiphenyl, bisphenol A, resorcinol, hydroquinone, pyrogallol and the like. The aforementioned aromatic hydroxyl compounds may be used alone or in combinations of two or more. Among those compounds, o-cresol, m-cresol, p-cresol, 2,5-dimethylphenol, 3,5-dimethylphenol and 2,3,5-triethylphenol are preferred.

Examples of the aforementioned aldehyde that is suitable to condense with the aromatic hydroxyl compound include but are not limited to formaldehyde, paraformaldehyde, trioxane, acetaldehyde, propanal, butanal, trimethyl acetaldehyde, acrolein, crotonaldehyde, cyclohexanealdehyde, furfural, furylacrolein, benzaldehyde, terephthal aldehyde, phenylacetaldehyde, α-phenylpropanal, β-phenylpropanal, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde, cinnamaldehyde and the like. The aforementioned aldehydes may be used alone or in combinations of two or more. Among those aldehydes, formaldehyde is preferred.

In one preferred embodiment of the invention, the novolac resin (A) includes a high-ortho novolac resin (A-1), and other novolac resins bond to methylene in a ortho-para, para-para or ortho-ortho position randomly.

The high-ortho novolac resin (A-1) according to the invention usually has 18% to 25% of ortho-ortho methylene bonding; preferably 19% to 25% of ortho-ortho methylene bonding; more preferably 20% to 25% of ortho-ortho methylene bonding.

The high-ortho novolac resin (A-1) according to the invention is generally prepared by condensing the above-mentioned aromatic hydroxyl compound with the aldehyde in the presence of a two-valent metal salt catalyst under an acidic environment (for example, pH 1 to 5), followed by dehydration under the reduced pressure. Alternatively, an acid catalyst can be further added in the dehydration condensation reaction, and unreactive monomers are removed. The details of the dehydration condensation reaction can be referred to Japanese Patent Publication No. 55-090523, Japanese Patent Publication No. 59-080418 and Japanese Patent Publication No. 62-230815 without reciting it in detail.

In the preferred embodiment of the invention, during the preparation of the high-ortho novolac resin (A-1), the aromatic hydroxyl compound and the aldehyde are typically used in a molar ratio of 1:0.5 to 1:0.85, preferably 1:0.55 to 1:0.82 and more preferably 1:0.6 to 1:0.8.

Examples of the aforementioned two-valent metal salt catalyst include but are not limited to zinc acetate, manganese acetate, barium acetate, manganese nitrate, zinc borate, zinc chloride, zinc oxide and the like. The aforementioned two-valent metal salt catalysts may be used alone or in combinations of two or more. Based on 100 parts by weight of the aromatic hydroxyl compound used, an amount of the two-valent metal salt catalyst used is typically 0.01 to 1.0 parts by weight, preferably 0.03 to 0.8 parts by weight, and more preferably 0.05 to 0.5 parts by weight.

Examples of the aforementioned acid catalyst include but are not limited to dimethyl sulfate, diethyl sulfate, dipropyl sulfate and the like. The aforementioned acid catalysts may be used alone or in combinations of two or more. Based on 100 parts by weight of the aromatic hydroxyl compound used, an amount of the acid catalyst used is typically 0.005 to 1.0 parts by weight, preferably 0.008 to 0.8 parts by weight and more preferably 0.01 to 0.5 parts by weight.

In one preferred embodiment of the invention, the amount of the high-ortho novolac resin (A-1) used is from 30 to 100 parts by weight; preferably from 40 to 100 parts by weight; more preferably from 50 to 100 parts by weight based on 100 parts by weight of the novolac resin (A) used for further improving the temporal stability.

As used herein, the ortho-naphthoquinone diazide sulfonic acid ester (B) can use the ones that are used widely in the prior art but have no specific limitation. Preferably, the ortho-naphthoquinone diazide sulfonic acid ester (B) can be an ester of an ortho-naphthoquinone diazide sulfonic acid and a hydroxy compound, in which the ortho-naphthoquinone diazide sulfonic acid is exemplified as ortho-naphthoquinone diazide-4-sulfonic acid, ortho-naphthoquinone diazide-5-sulfonic acid and ortho-naphthoquinone diazide-6-sulfonic acid. More preferably, the ortho-naphthoquinone diazide sulfonic acid ester (B) can be an ester of the ortho-naphthoquinone diazide sulfonic acid and a polyhydroxy compound. The aforementioned esters can be completely or partially esterified. Examples of the hydroxy compound can be (1) hydroxybenzophenones; (2) hydroxyaromatic compounds of formula (13); (3) (hydroxyphenyl)hydrocarbons of formula (14); (4) other aromatic hydroxy compounds and the like and illustrated as bellows.

(1) Hydroxybenzophenones are exemplified as 2,3,4-trihydroxybenzophenone, 2,4,4′-trihydroxybenzophenone, 2,4,6-trihydroxybenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5′-pentahydroxybenzophenone, 2,3′,4,5,5′-pentahydroxybenzophenone, 2,3,3′,4,4′,5′-hexahydroxybenzophenone and the like.

(2) Hydroxyaromatic compounds are exemplified as the following formula (13):

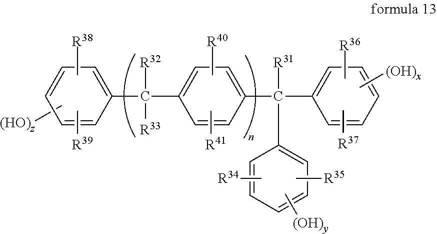

wherein:
R³¹, R³² and R³³ represent a hydrogen atom or a C₁ to C₆ alkyl group;
R³⁴, R³⁵, R³⁶, R³⁷, R³⁸ and R³⁹ represent a hydrogen atom, a halogen atom, a C₁ to C₆ alkyl group, a C₁ to C₆ alkoxy group, a C₁ to C₆ alkenyl group or a cycloalkyl group;
R⁴⁰ and R⁴¹ represent a hydrogen atom, a halogen atom, or a C₁ to C₆ alkyl group;
x, y and z independently represent an integer of 1 to 3; and
n represent an integer of 0 to 1.

Specific examples of the hydroxyaromatic compound of the formula (13) include but are not limited to tris(4-hydroxyphenyl)methane, bis(4-hydroxy-3,5-dimethylphenyl)-4-hydroxyphenyl methane, bis(4-hydroxy-3,5-dimethylphenyl)-3-hydroxyphenyl methane, bis(4-hydroxy-3,5-dimethylphenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-dihydroxyphenyl methane, bis(4-hydroxy-2,5-dimethylphenyl)-3,4-dihydroxyphenyl methane, bis(4-hydroxy-3,5-dimethylphenyl)-2,4-dihydroxyphenyl methane, bis(4-hydroxy-2,5-dimethylphenyl)-2,4-dihydroxyphenyl methane, bis(4-hydroxyphenyl)-3-methoxy-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-methylphenyl)-2-hydroxyphenyl methane, bis(3-cyclohexyl-4-hydroxy-6-methylphenyl)-3-hydroxyphenyl methane, bis(3-cyclohexyl-4-hydroxy-6-methylphenyl)-4-hydroxyphenyl methane, bis(3-cyclohexyl-4-hydroxy-6-methylphenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methylphenyl)-3,4-dihydroxyphenyl methane, 1-[1-(4-hydroxylphenyl)isopropyl]-4-[1,1-bis(4-hydroxylphenyl)ethyl]benzene, 1-[1-(3-methyl-4-hydroxylphenyl)isopropyl]-4-[1,1-bis(3-methyl-4-hydroxylphenyl)ethyl]benzene.

(3) (Hydroxyphenyl)hydrocarbons are exemplified as the following formula (14):

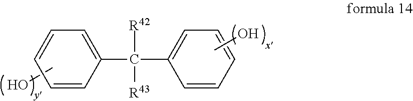

wherein:
R⁴² and R⁴³ represent a hydrogen atom or a C₁ to C₆ alkyl group; and
x′ and y′ independently represent an integer of 1 to 3.

Specific examples of the (hydroxyphenyl)hydrocarbon of the formula (14) include but are not limited to 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, bis(2,3,4-trihydroxyphenyl)methane, bis(2,4-dihydroxyphenyl)methane and the like.

(4) Other aromatic hydroxy compounds are exemplified as phenol, p-methoxy phenol, dimethyl phenol, hydroquinone, bisphenol A, naphthol, pyrocatechol, 1,2,3-pyrogallol monomethyl ether, 1,2,3-pyrogallol-1,3-dimethyl ether, 3,4,5-trihydroxybenzoic acid (gallic acid), partially esterified or partially etherified gallic acid and the like.

Among those hydroxy compounds, 2,3,4-trihydroxybenzophenone and 2,3,4,4′-tetrahydroxybenzophenone are preferable. The aforementioned hydroxy compounds may be used alone or in combinations of two or more.

The ortho-naphthoquinone diazide sulfonic acid ester (B) in the positive photosensitive resin composition according to the present can use a quinone diazide compound such as ortho-naphthoquinone diazide-4-(or -5-) sulfonyl halide salt, followed by condensation with (1) to (4) of the hydroxy compounds to achieve complete or partial esterification. The aforementioned condensation is usually carried out in an organic solvent such as dioxane, N-pyrrolidone, acetamide or the like. Simultaneously, the condensation is more advantageously carried out in the presence of an alkaline condensing agent such as triethanolamine, alkali metal carbonate or alkali metal bicarbonate or the like.

Based on 100 mole percents of the total hydroxy group of the hydroxy compound, esterification of the ortho-naphthoquinone diazide-4-(or -5-) sulfonyl halide salt is preferably condensed with 50 mole percents of hydroxy group the hydroxy compound, and more preferably condensed with 60 mole percents of hydroxy group the hydroxy compound. In other word, the esterification degree is equal to or more than 50 percents, and more preferably more than 60 percents.

In one preferred embodiment of the invention, the amount of the ortho-naphthoquinone diazide sulfonic acid ester (B) used is from 1 to 100 parts by weight; preferably from 5 to 80 parts by weight; more preferably from 10 to 60 parts by weight based on 100 parts by weight of the novolac resin (A).

The dye (C) according to the invention comprises a dye (C-1) and a dye (C-2), and the dye (C-1) is selected from the group consisting of a disazo dye, an anthraquinone dye, and a trivalent chromium azo dye; and the dye (C-2) is a triarylmethane dye. If the dye (C-1) or the dye (C-2) are absent, the temporal stability of viscosity and sensitivity is not satisfactory.

The disazo dye according to the invention can be chosen by artisans skilled in this field. Several commercialized products of the disazo dye are ready for chosen, such as C.I. Acid Black 1, C.I. Acid Black 24, C.I. Reactive Black 5, C.I. Solvent Black 3 (trade name of Sudan Black 141; manufactured by Chuo synthetic Chemical Co, trade name of Neptun Black X60; manufactured by BASF), and Oil Black DA-41 manufactured by NEMOTO & CO., LTD.

The anthraquinone dye according to the invention can be chosen by artisans skilled in this field. Several commercialized products of the anthraquinone dye are ready for chosen, such as C.I. Solvent Red 52, C.I. Solvent Red 111, C.I. Solvent Red 149, C.I. Solvent Red 150, C.I. Solvent Red 151, C.I. Solvent Red 168, C.I. Solvent Red 191, C.I. Solvent Red 207, C.I. Solvent Blue 35, C.I. Solvent Blue 36, C.I. Solvent Blue 63, C.I. Solvent Blue 78, C.I. Solvent Blue 83, C.I. Solvent Blue 87, C.I. Solvent Blue 94, C.I. Solvent Blue 97, C.I. Solvent Blue 101, C.I. Solvent Green 3, C.I. Solvent Green 20, C.I. Solvent Green 28, C.I. Solvent Violet 13, C.I. Solvent Violet 14, C.I. Solvent Violet 36, C.I. Disperse Red 22, C.I. Disperse Red 60, C.I. Disperse Violet 31, C.I. Disperse Violet 28, C.I. Vat Black 27, and Kayaset Black A-N manufactured by Nippon Kayaku CO., LTD.

The trivalent chromium azo dye according to the invention can be chosen by artisans skilled in this field. Several commercialized products of the trivalent chromium azo dye are ready for chosen, such as Solvent Black 27 (trade name of Neozapon Black X51; manufactured by BASF, trade name of Van CHAKU Black Z1-1500; manufactured by Gen Gen Corporation), Solvent Black 29 (trade name of VALIFAST BLACK 3808; manufactured by ORIENT CHEMICALS), C.I. Solvent Black 34 (trade name of VALIFAST BLACK 3804; manufactured by ORIENT CHEMICALS).

The aforementioned dye (C-1) may be used alone or in combinations of two or more.

The dye (C-2) according to the invention can be chosen by artisans skilled in this field. In one preferred embodiment of the invention, the dye (C-2) has a structure represented by the following general formula (1) or formula (2) or a salt thereof,

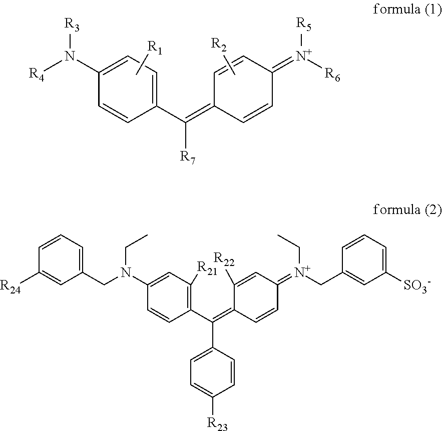

wherein in formula (1),
R₁ and R₂ are independently selected from the group consisting of a hydrogen atom, a halogen atom and a C₁ to C₅ alkyl group;
R₃, R₄, R₅, and R₆ are independently selected from the group consisting of a hydrogen atom, a C₁ to C₅ alkyl group, a phenyl group and a benzyl group; and
R₇ is selected from the group consisting of the general formula (3), formula (4) and formula (5),

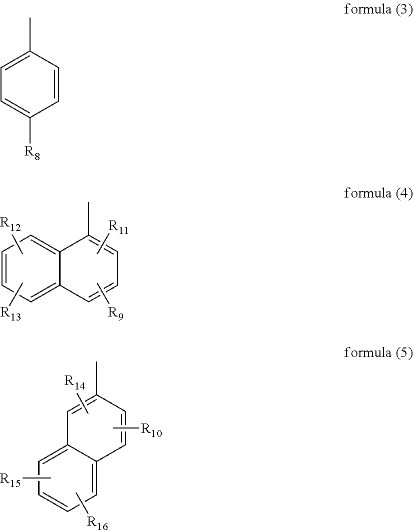

wherein:
R₈ to R₁₀ are selected from the group consisting of a hydrogen atom and —NR₂₅R₂₆;
   wherein:
   R₂₅ and R₂₆ are independently selected from the group consisting of a hydrogen atom, a C₁ to C₅ alkyl group, a benzyl group, a phenyl group, and a phenyl group substituted by a C₁ to C₃ alkoxy group or by a C₁ to C₃ alkyl group in the para position; and
R₁₁ to R₁₆ are independently selected from the group consisting of a hydrogen atom, a hydroxyl group and —SO³⁻;
wherein in formula (2),
R₂₁ and R₂₂ are independently selected from the group consisting of a hydrogen atom, a halogen atom, and a C₁ to C₅ alkyl group; and
R₂₃ is selected from the group consisting of a hydrogen atom, —SO³⁻, a carboxyl group, a C₁ to C₃ alkyl group, a C₁ to C₃ alkoxyl group, and —NR₂₅R₂₆; and
R₂₄ is selected from the group consisting of a hydrogen atom and —SO³⁻.

Preferably, the C₁ to C₃ alkyl group of the R₂₁, R₂₂, R₂₃, R₂₅ and R₂₆ is a methyl group, an ethyl group or a propyl group; the C₁ to C₃ alkoxy group of the R₈ and R₂₃ is a methoxy group, an ethoxy group or a propoxy group; the phenyl group substituted by a C₁ to C₃ alkoxy group in the para position of the R₂₅ and R₂₆ is a p-methoxyphenyl group, a p-ethoxyphenyl group, or a p-propoxyphenyl.

The triarylmethane dye (C-2) according to the invention can be a salt of the structure represented by the following general formula (1) or formula (2), such as an alkali metal salt of sodium, potassium, or the like; an amine salt of triethylamine of 2-ethylhexyl amine, 1-amino-3-diphenyl butane, or the like. The salt can also be a salt formed with —SO³⁻.

Several commercialized products of the triarylmethane dye (C-2) are ready for chosen, such as C. I. Acid Green 3, C. I. Acid Green 9, C. I. Acid Green 16, C. I. Acid Green 50, C. I. Acid Blue 7, C. I. Acid Blue 83 (trade name of Brilliant Blue R; manufactured by Trust Chem), C. I. Acid Blue 90, C. I. Acid Blue 108, C. I. Acid Violet 17 (trade name of Coomassie Violet R200; manufactured by Sigma), C. I. Acid Violet 49, C.I. Solvent Green 15, C.I. Solvent Violet 8, C.I. Basic Blue 1, C.I. Basic Blue 5, C.I. Basic Blue 7 (trade name of Basonyl Blau 636; manufactured by BASF), C.I. Basic Blue 8, C.I. Basic Blue 26, C. I. Solvent Blue 5, C. I. Solvent Blue 38, C.I. Basic Green 1, C.I. Basic Red 9, C.I. Basic Violet 3, C.I. Basic Violet 12, C.I. Basic Violet 14, Methyl Violet, Crystal Violet, Victoria Blue B, Oil Blue 613 (manufactured by ORIENT CHEMICALS), VALIFAST Blue 1621 (manufactured by ORIENT CHEMICALS), SBN Blue 701 (manufactured by Hodogaya Chemical Co., Ltd) and derivatives thereof.

The aforementioned triarylmethane dye (C-2) may be used alone or in combinations of two or more.

Preferably, the dye (C) further comprises a dye (C-3), and the dye (C-3) is a phthalocyanine dye. The phthalocyanine dye according to the invention is preferably represented by the following general formula (6),

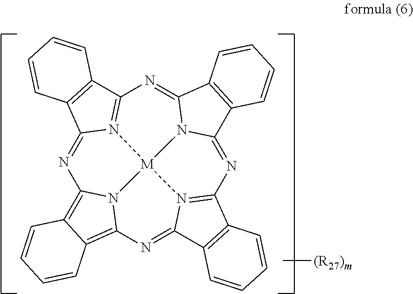

wherein:
R₂₇ represents a substituent, and preferably is a substituent represented by Rₐ₁ to Rₐ₈ and R_{b1} to R_{b8} in the following formula (7);
m represents an integer of 1 to 8; preferably 1 to 6; more preferably 1 to 4; when m is an integer larger than 2, the multiple R₂₇ can be the same of different; and
M is selected from the group consisting of a metal, a metal chloride, a metal oxide and a metal hydroxide. Preferably, the metal is selected from the group consisting of zinc, magnesium, silicon, tin, rhodium, platinum, palladium, molybdenum, manganese, lead, copper, nickel, cobalt and iron; the metal chloride is selected from the group consisting of AlCl, InCl, FeCl, TiCl₂, SnCl₂, SiCl₂, and GeCl₂; the metal oxide is selected from the group consisting of TiO and VO; the metal hydroxide is Si(OH)₂; more preferably, M is selected from the group consisting of zinc, palladium, copper, nickel, cobalt, and VO; still more preferably, M is selected from the group consisting of zinc, copper, cobalt and VO; most preferably, M is copper.

In one embodiment of the invention, the phthalocyanine dye according to the invention is preferably represented by the following general formula (7),

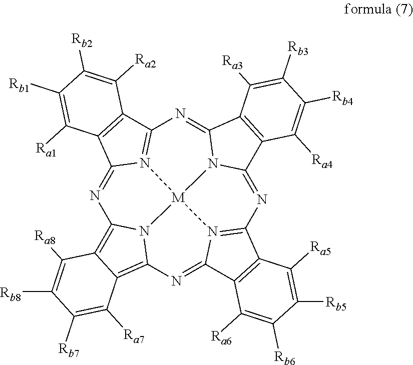

wherein:

Rₐ₁ to Rₐ₈ and R_{b1} to R_{b8} are respectively independently selected from the group consisting of a hydrogen atom, a halogen atom, a cyano group, a nitro group, a formyl group, a carboxyl group, a sulfo group, a substituted or unsubstituted C₁ to C₂₀ alkyl group, a substituted or unsubstituted C₆ to C₂₄ aryl group, a substituted or unsubstituted C₁ to C₁₀ heterocyclic group, a substituted or unsubstituted C₁ to C₂₀ alkoxy group, a substituted or unsubstituted C₆ to C₁₄ aryloxy group, a substituted or unsubstituted C₂ to C₂₁ acyl group, a substituted or unsubstituted C₁ to C₂₀ alkylsulfonyl group, a substituted or unsubstituted C₆ to C₁₄ arylsulfonyl group, a substituted or unsubstituted C₁ to C₁₀ heterysulfonyl group, a substituted or unsubstituted C₁ to C₂₅ carbamoyl group, a substituted or unsubstituted C₀ to C₃₂ sulfamoyl group, a substituted or unsubstituted C₁ to C₂₀ alkoxycarbonyl group, a substituted or unsubstituted C₇ to C₁₅ aryloxycarbonyl group, a substituted or unsubstituted C₂ to C₂₁ acylamino group, a substituted or unsubstituted C₁ to C₂₀ sulfonylamino group, and a substituted or unsubstituted C₀ to C₃₆ amino group; wherein the amino group contains an anilino group. Furthermore, at least eight of the Rₐ₁ to Rₐ₈ and R_{b1} to R_{b8} are a hydrogen atom and Rₐ₁ to Rₐ₈ are not all a hydrogen atom to enhance the solubility to the solvent.

Preferably, Rₐ₁ to Rₐ₈ and R_{b1} to R_{b8} are respectively independently selected from the group consisting of a hydrogen atom, a halogen atom, a carboxyl group, a sulfo group, a substituted or unsubstituted C₁ to C₁₆ alkyl group (such as a methyl group, an ethyl group, a n-propyl group and an isopropyl group), a substituted or unsubstituted C₆ to C₂₄ aryl group (such as a phenyl group, a p-methoxyphenyl group, a p-octadecylphenyl group), a substituted or unsubstituted C₁ to C₁₆ alkoxy group (such as a methoxy group, an ethoxy group, a n-octyloxy group), a substituted or unsubstituted C₆ to C₁₀ aryloxy group (such as a phenoxy group, a p-ethoxyphenoxy), a substituted or unsubstituted C₁ to C₂₀ alkylsulfonyl group (such as a methyl sulfonyl group, an n-propyl sulfonyl group, an n-octyl sulfonyl group), a substituted or unsubstituted C₆ to C₁₄ arylsulfonyl group (such as a tolyl sulfonamide group, a phenyl sulfonamide group), a substituted or unsubstituted C₀ to C₂₀ sulfamoyl group (such as a methyl sulfamoyl group, an n-butyl sulfamoyl group), a substituted or unsubstituted C₁ to C₁₇ alkoxycarbonyl group (such as a methoxylcarbonyl group, an n-butoxylcarbonyl group), a substituted or unsubstituted C₇ to C₁₅ aryloxycarbonyl group (such as a phenoxycarbonyl group), a substituted or unsubstituted C₂ to C₂₁ acylamino group (such as an acetamino group, a trimethyl acetamino group), and a substituted or unsubstituted C₁ to C₁₈ sulfonylamino group (such as a methyl sulfonylamino group, an n-butylsulfonylamino group).

More preferably, Rₐ₁ to Rₐ₈ and R_{b1} to R_{b8} are respectively independently selected from the group consisting of a hydrogen atom, a halogen atom, a carboxyl group, a sulfo group, a substituted or unsubstituted C₁ to C₁₆ alkyl group, a substituted or unsubstituted C₁ to C₁₆ alkoxy group, a substituted or unsubstituted C₁ to C₂₀ alkylsulfonyl group, a substituted or unsubstituted C₆ to C₁₄ arylsulfonyl group, a substituted or unsubstituted C₂ to C₂₀ sulfamoyl group, a substituted or unsubstituted C₁ to C₁₃ alkoxycarbonyl group, a substituted or unsubstituted C₂ to C₂₁ acylamino group, and a substituted or unsubstituted C₁ to C₁₈ sulfonylamino group.

Still more preferably, Rₐ₁ to Rₐ₈ are respectively independently selected from the group consisting of a hydrogen atom, a halogen atom, a sulfo group, a substituted or unsubstituted C₁ to C₁₆ alkoxy group, a substituted or unsubstituted C₁ to C₂₀ alkylsulfonyl group, a substituted or unsubstituted C₆ to C₁₄ arylsulfonyl group, a substituted or unsubstituted C₂ to C₂₀ sulfamoyl group, a substituted or unsubstituted C₂ to C₂₁ acylamino group, and a substituted or unsubstituted C₁ to C₁₈ sulfonylamino group; R_{b1} to R_{b8} are a hydrogen atom or a halogen atom.

Most preferably, Rₐ₁ to Rₐ₈ are respectively independently selected from the group consisting of a hydrogen atom, a sulfo group, a substituted or unsubstituted C₁ to C₂₀ alkylsulfonyl group, a substituted or unsubstituted C₆ to C₁₄ arylsulfonyl group, and a substituted or unsubstituted C₇ to C₂₀ sulfamoyl group; R_{b1} to R_{b8} are a hydrogen atom.

Furthermore, any one of Rₐ₁ and Rₐ₂, any one of Rₐ₁ and Rₐ₄, any one of Rₐ₅ and Rₐ₆, and any one of Rₐ₇ and Rₐ₈ are preferably not all a hydrogen atom to enhance the solubility to the solvent.

When the groups represents by Rₐ₁ to Rₐ₈ and R_{b1} to R_{b8} are substituted, the substituents are exampled as follows.

A substituted or unsubstituted C₁ to C₂₀ linear or cyclic alkyl group (such as a methyl group, an ethyl group, an isopropyl group, a cyclohexyl group, a benzyl group, a phenethyl group), a substituted or unsubstituted C₆ to C₁₈ aryl group (such as a phenyl group, a chlorophenyl group, a 2,4-ditert-butylphenyl group, an 1-naphthyl group), a substituted or unsubstituted C₂ to C₂₀ alkenyl group (such as an ethenyl group, a 2-methylvinyl group), a substituted or unsubstituted C₂ to C₂₀ alkynyl group (such as an ethynyl group, a 2-methylethynyl group, a 2-phenylethynyl group), a halogen atom (such as a fluorine atom, a chlorine atom, a bromine atom, an iodine atom), a cyano group, a hydroxyl group, a carboxyl group, a substituted or unsubstituted C₂ to C₂₀ acyl group (such as an acetyl group, a benzoyl group, a salicylic acyl group, a trimethylacetyl group), a substituted or unsubstituted C₁ to C₂₀ alkoxyl group (such as a methoxy group, a butoxy group, a cyclohexyloxy group), a substituted or unsubstituted C₆ to C₂₀ aryloxy group (such as a phenoxy group, an 1-naphthyloxy group, a p-methoxy phenyl group), a substituted or unsubstituted C₁ to C₂₀ alkylthio group (such as a methylthio group, a butylthio group, a benzylthio group, a 3-methoxypropyl thio group), a substituted or unsubstituted C₆ to C₂₀ arylthio group (such as a phenylthio group, a 4-chlorophenylthio group), a substituted or unsubstituted C₁ to C₂₀ alkylsulfonyl group (such as a methyl sulfonyl group, an n-propyl sulfonyl group), a substituted or unsubstituted C₆ to C₂₀ arylsulfonyl group (such as a phenyl sulfonamide group, a p-tolyl sulfonamide group), a substituted or unsubstituted C₁ to C₁₇ carbamoyl group (such as an unsubstituted carbamoyl group, a methyl carbamoyl group, an ethyl carbamoyl group, an n-butyl carbamoyl group, a dimethyl carbamoyl group), a substituted or unsubstituted C₁ to C₁₆ acylamino group (such as an acetamino group, a benzamino group), a substituted or unsubstituted C₂ to C₂₀ acyloxy group (such as an acetoxy group, a benzoxy group), a substituted or unsubstituted C₂ to C₂₀ alkoxycarbonyl group (such as a methoxylcarbonyl group, an ethoxylcarbonyl group), a substituted or unsubstituted 5-membered or 6-membered heterocyclic group (such as an aromatic heterocyclic group of a pyridyl group, a thienyl group, a furyl group, a thiazolyl group, a imidazolyl group, a pyrazolyl group; or a non-aromatic heterocyclic group of a pyrrolidino group, a piperidino group, a morpholino group, a pyrano group, a thiopyrano group, a dioxano group, a dithiolane group).

Preferably, the substitutents represents by Rₐ₁ to Rₐ₈ and R_{b1} to R_{b8} are selected from the group consisting of a substituted or unsubstituted C₁ to C₁₆ linear or cyclic alkyl group, a substituted or unsubstituted C₆ to C₁₄ aryl group, a substituted or unsubstituted C₁ to C₁₆ alkoxyl group, a substituted or unsubstituted C₆ to C₁₄ aryloxy group, a halogen atom, a substituted or unsubstituted C₂ to C₁₇ alkoxycarbonyl group, a substituted or unsubstituted C₁ to C₁₀ carbamoyl group, and a substituted or unsubstituted C₁ to C₁₀ acylamino group.

More preferably, the substitutents represents by Rₐ₁ to Rₐ₈ and R_{b1} to R_{b8} are selected from the group consisting of a substituted or unsubstituted C₁ to C₁₀ linear or cyclic alkyl group, a substituted or unsubstituted C₆ to C₁₀ aryl group, a substituted or unsubstituted C₁ to C₁₀ alkoxyl group, a substituted or unsubstituted C₆ to C₁₀ aryloxy group, a chloride atom, a substituted or unsubstituted C₂ to C₁₁ alkoxycarbonyl group, a substituted or unsubstituted C₁ to C₇ carbamoyl group, and a substituted or unsubstituted C₁ to C₈ acylamino group.

Still more preferably, the substitutents represents by Rₐ₁ to Rₐ₈ and R_{b1} to R_{b8} are selected from the group consisting of an unsubstituted C₁ to C₈ linear or cyclic alkyl group, an unsubstituted C₁ to C₈ alkoxyl group, an unsubstituted C₃ to C₉ alkoxycarbonyl group, a chloride atom, and a phenyl. Most preferably, the substitutents represents by Rₐ₁ to Rₐ₈ and R_{b1} to R_{b8} are an unsubstituted C₁ to C₆ alkoxyl group.

The compound represented by the general formula (6) or (7) according to the invention can form a polymer in any position, and the units thereof can be the same or different, and can also bind to the polymer of polystyrene, polymethylacrylate, polyvinyl alcohol, or cellulose.

The aforementioned compound represented by the general formula (6) or (7) may be used alone or in combinations of two or more. Preferably, it is a combination of isomers having substituents in different positions.

In the preferred embodiment of the invention, the phthalocyanine dye (C-3) is represented by the following general formula (8), formula (9), formula (10), formula (11), or formula (12),

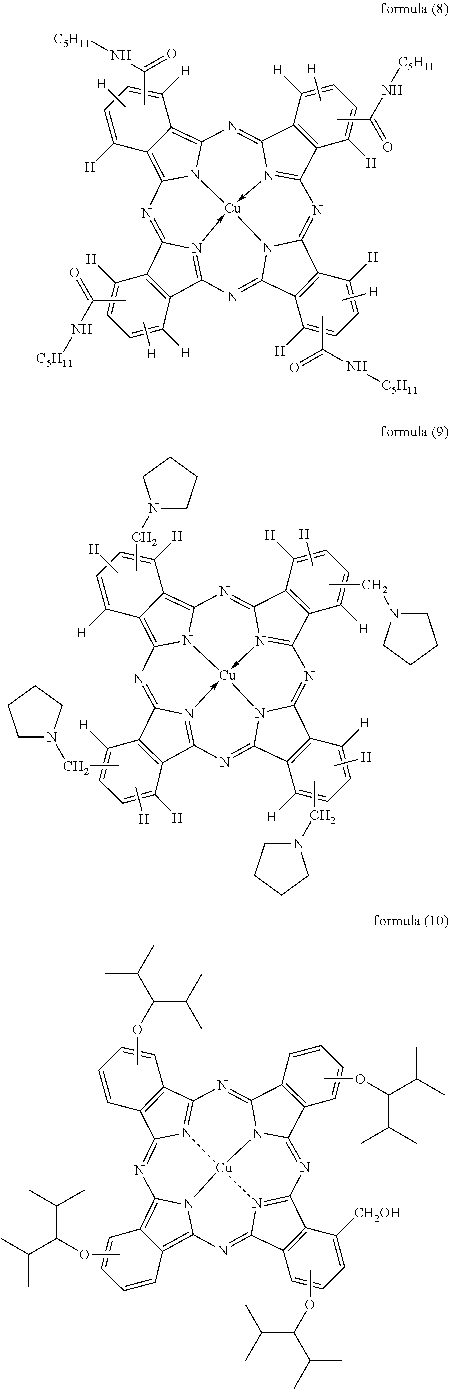

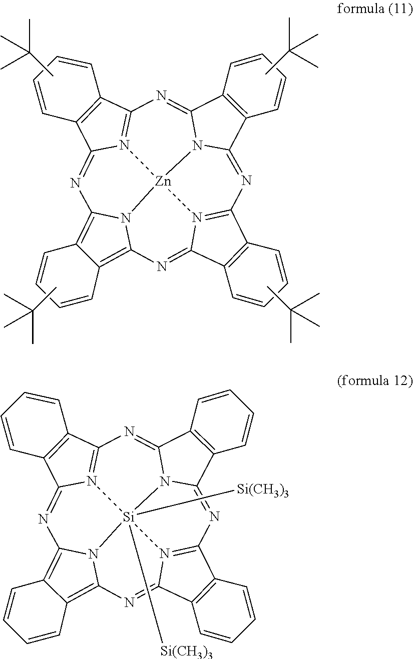

Several commercialized products of the phthalocyanine dye (C-3) are ready for chosen, such as C.I. Acid Blue 249, C.I. Solvent Blue 25, C.I. Solvent Blue 55, Solvent Blue 64 (trade name of Neptun Blue 698), Solvent Blue 67, C.I. Solvent Blue 70 (trade name of Neozapon Blue 807; manufactured by BASF), C.I. Direct Blue 199, C.I. Direct Blue 86 (trade name of Turquoise Blue; manufactured by Italia Incorporation).

If the phthalocyanine dye (C-3) is used, the temporal stability of viscosity is further improved.

In one preferred embodiment of the invention, the positive photosensitive resin composition further comprises a perinone dye, a perylene dye, an azo dye, a methane dye, a quinoline dye, an azine dye, an anthraquinone dye, an indigo dye, an oxonol dye, a thiazine dye, an anthrapyridone dye, a xanthene dye or a benzopyran dye as needed.

In one preferred embodiment of the invention, the amount of the dye (C) used is from 10 to 35 parts by weight; preferably from 12 to 30 parts by weight; more preferably from 15 to 25 parts by weight based on 100 parts by weight of the novolac resin (A) used.

In one preferred embodiment of the invention, the amount of the dye (C-1) used is from 2 to 15 parts by weight; preferably from 3 to 12 parts by weight; more preferably from 5 to 10 parts by weight; the amount of the dye (C-2) used is from 1 to 10 parts by weight; preferably from 2 to 9 parts by weight; more preferably from 3 to 8 parts by weight; the amount of the dye (C-3) used is from 5 to 30 parts by weight; preferably from 7 to 28 parts by weight; more preferably from 10 to 25 parts by weight based on 100 parts by weight of the novolac resin (A) used.

The solvent (D) as used herein refers to an organic solvent that is dissolved but not reacted with other organic components.

Specific examples of the solvent (D) include but are not limited to (poly)alkylene glycol monoalkyl ethers such as ethylene glycol monomethyl ether, ethylene glycol monoethyl ether, diethylene glycol monoethyl ether, diethylene glycol mono-n-propyl ether, diethylene glycol mono-n-butyl ether, trimethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monoethyl ether, tripropylene glycol monoethyl ether and the like; (poly)alkylene glycol monoalkyl ether acetates such as ethylene glycol monomethyl ether acetate, ethylene glycol monoethyl ether acetate, propylene glycol monomethyl ether acetate, propylene glycol monoethyl ether acetate and the like; other ethers such as diethylene glycol dimethyl ether, diethylene glycol methyl ethyl ether, diethylene glycol diethyl ether, tetrahydrofuran and the like; ketones such as methyl ethyl ketone, cyclohexanone, 2-heptanone, 3-heptanone and the like; alkyl lactates such as methyl 2-hydroxypropanoate, ethyl 2-hydroxypropanoate(ethyl lactate) and the like; other esters such as methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate, ethyl ethoxyacetate, ethyl hydroxyacetate, methyl 2-hydroxy-3-methylenebutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate and the like; aromatic hydrocarbons such as toluene, xylene and the like; carboxylic amines such as N-methylpyrrolidone, N,N-dimethylformamide, N,N-dimethylacetamide and the like. The solvent (D) may be used alone or in combinations of two or more. Among those solvents, propylene glycol monoethyl ether, propylene glycol monomethyl ether acetate and ethyl lactate are preferred.

In one preferred embodiment of the invention, the amount of the solvent (D) used is from 500 to 2,000 parts by weight; preferably from 600 to 1,800 parts by weight; more preferably from 700 to 1,500 parts by weight based on 100 parts by weight of the novolac resin (A) used.

The positive photosensitive resin composition according to the invention preferably further includes an additive (E) that includes but is not limited to an adhesiveness improver, a surface-leveling agent, a diluent, a sensitizer and the like.

Examples of the adhesiveness improver include but are not limited to a melamine compound and a silane compound, thereby strengthening the adhesiveness of the positive photosensitive resin composition attached on the substrate. Specific examples of the melamine compound include but are not limited to the products available commercially as Cymel-300 and Cymel-303 (CYTEC Industries Inc., NJ, U.S.A); and MW-30 MH, MW-30, MS-11, MS-001, MX-750 and MX-706 (Sanwa Chemical Co., Ltd, Japan). Specific examples of the silane compound, include but are not limited to vinyltrimethoxysilane, vinyltriethoxysilane, vinyl tris(2-methoxyethoxy) silane, N-(2-aminoethyl)-3-aminopropyl methyl dimethoxysilane, N-(2-aminoethyl)-3-aminopropyl trimethoxysilane, 3-aminopropyl triethoxysilane, 3-glycidoxypropyltrimetoxysilane, 3-glycidoxypropylmethyldimetoxysilane, 2-(3,4-epoxycyclohexyl)ethyltrimethoxysilane, 3-chloropropylmethyldimetoxysilane, 3-chloropropyltrimetoxysilane, 3-methacryloxy propyl trimethoxysilane, 3-mercapto propyltrimethoxysilane, bis(1,2-trimethoxysilyl)ethane.

In one preferred embodiment of the invention, the amount of the melamine compound used is from 0 to 20 parts by weight; preferably from 0.5 to 18 parts by weight; more preferably from 1.0 to 15 parts by weight; the amount of the silane compound used is from 0 to 2 parts by weight; preferably from 0.001 to 1 parts by weight; more preferably from 0.005 to 0.8 parts by weight based on 100 parts by weight of the novolac resin (A) used for further improving the temporal stability.

Examples of the aforementioned surface-leveling agent include but are not limited to a fluorosurfactant and a silicon-based surfactant. Specific examples of the fluorosurfactant include but are not limited to the products available commercially as trade names of Fluorad FC-430 and FC-431 (manufactured by 3M Specialty Materials Division, MN, U.S.A); and trade names of F top EF122A, 122B, 122C, 126 and BL20 (manufactured by Tochem product Co., Ltd). Specific examples of the silicon-based surfactant include but are not limited to the products available commercially as trade names of SF8427 and SH29PA (Dow Corning Toray Silicone Co., Ltd).

In one preferred embodiment of the invention, the amount of the surfactant used is from 0 to 1.2 parts by weight; preferably from 0.025 to 1.0 parts by weight; more preferably from 0.050 to 0.8 parts by weight based on 100 parts by weight of the novolac resin (A) used for further improving the temporal stability.

Specific examples of the diluent include but are not limited to the products available commercially as trade names of RE801 and RE802 (manufactured by Teikoku Printing Inks Mfg. Co., Ltd. JP).

Specific examples of the sensitizer include but are not limited to the products available commercially as trade names of TPPA-1000P, TPPA-100-2C, TPPA-1100-3C, TPPA-1100-4C, TPPA-1200-24X, TPPA-1200-26X, TPPA-1300-235T, TPPA-1600-3M6C and TPPA-MF (manufactured by Honsyu Chemical Industry Ltd., JP). Among those sensitizers, TPPA-1600-3M6C and TPPA-MF are preferred. The aforementioned sensitizers may be used alone or in combinations of two or more.

In one preferred embodiment of the invention, the amount of the sensitizer used is from 0 to 20 parts by weight; preferably from 0.5 to 18 parts by weight; more preferably from 1.0 to 15 parts by weight based on 100 parts by weight of the novolac resin (A) used for further improving the temporal stability.

In addition, the positive photosensitive resin composition can be added with other additives such as plasticizer, stabilizer and so on if needed.

The method for the preparation of the positive photosensitive resin composition according to the invention can be carried out by artisans skilled in this field. In one embodiment of the invention, the positive photosensitive resin composition is prepared by mixing the novolac resin (A), the ortho-naphthoquinone diazide sulfonic acid ester (B), the dye (C) and the solvent (D) well in a mixer until all components are formed into a solution state. The positive photosensitive resin composition is optionally added with the additive (E) such as the adhesiveness improver, the surface-leveling agent, the diluent, the sensitizer and so on if needed.

The present invention also provides a method for manufacturing a thin-film transistor array substrate. The thin-film transistor array substrate comprises a substrate and a pattern. The method comprises coating the positive photosensitive resin composition as mentioned above on the substrate to form the pattern.

In one embodiment of the invention, the positive photosensitive resin composition of the present invention can be subjected to a prebake step, an exposure step, a development step and a postbake step, so as to forming patterns on a substrate.

Specifically, in the method for forming patterns by using the positive photosensitive resin composition, the resin composition is applied on the substrate by various coating methods, for example, spin coating, cast coating or roll coating methods. And then, the coated resin composition is prebaked to remove the solvent, thereby forming a prebaked coating film. The prebake step is carried out in various conditions, for example, at 70 to 110° C. for 1 to 15 minutes, which depend upon the kinds and the mixing ratio of components.

After the prebake step, the prebaked coating film is exposed under a given mask, and immersed in a developing solution at 23±2° C. for 15 seconds to 5 minutes, thereby removing undesired areas and forming a given pattern. The exposure light is preferably g-line, h-line, i-line and so on, which may be generated by a UV illumination device such as (super) high-pressure mercury lamp or metal halide lamp.

Specific examples of the developing solution include but are not limited to alkaline compounds such as sodium hydroxide, potassium hydroxide, sodium carbonate, sodium bicarbonate, potassium carbonate, potassium bicarbonate, sodium silicate, sodium methyl silicate, ammonia solution, ethylamine, diethylamine, dimethylethylanolamine, tetramethylammonium hydroxide, tetraethylammonium hydroxide, choline, pyrrole, piperidine, 1,8-diazabicyclo-[5,4,0]-7-undecene and the like.

The concentration of the developing solution is preferably 0.001 weight percent (wt %) to 10 wt %, more preferably 0.005 wt % to 5 wt %, and much more preferably 0.01 wt % to 1 wt %.

When the aforementioned alkaline compounds are included in the developing solution, the coating film can be washed by water after being developed, and then be dried by compressed air or nitrogen gas. Next, the coating film is postbaked by using a hot plate, an oven or other heating device. The postbake step can be carried out at 100 to 250° C. for 1 to 60 minutes on the hot plate for 5 to 90 minutes 1 n the oven. After those steps, the pattern is formed on the substrate.

The present invention also provides a thin-film transistor array substrate manufactured according to the method as mentioned above.

In one embodiment of the invention, the positive photosensitive resin composition is applied on a substrate by various coating methods, for example, spin coating, cast coating or roll coating methods, for forming a positive photoresist layer, in which the aforementioned substrate is a glass or plastic substrate with a film of aluminum, chromium, silicon nitride or amorphous silicon formed thereon. Next, through the prebake, exposure, development and post bake steps for forming the photosensitive resin pattern, the pattern is etched and then the photoresist is stripped. Those steps are repeated for obtaining the TFT array substrate with one or more TFTs or electrodes disposed thereon.

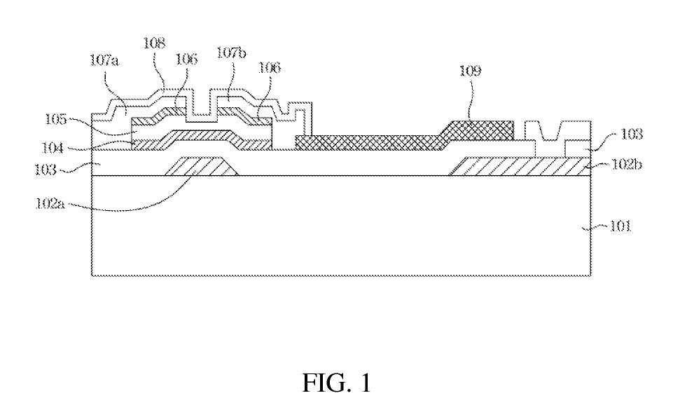

Reference is made to FIG. 1, which depicts a partial cross-sectional diagram of a TFT array substrate for a LCD device according to an embodiment of the present invention. First of all, a gate 102a and a storage capacitance Cs electrode 102b are disposed on an aluminum film of a glass substrate 101. Next, a silicon oxide (SiOₓ) film 103 or a silicon nitride (SiNₓ) film 104 each of which functions as an insulation film is covered over the gate 102a. And then, an amorphous silicon (a-Si) film 105 that functions as a semiconductor active layer is formed on the insulation film. Next, another a-Si film 106 doped with nitrogen impurity is disposed on the a-Si film 105 for reducing the interface resistance. Later, a drain 107a and a source 107b are formed by using a metal such as aluminum or the like, in which the drain 107a is connected to a data signal line (unshown), and the source 107b is connected to the pixel electrode (or sub-pixel electrode) 109. Subsequently, another silicon nitride film is disposed which functions as a protection film 108 for protecting the a-Si film 105 (as the semiconductor active layer), the drain 107a or the source 107b.

The present invention also provides a liquid crystal display device comprising the thin-film transistor array substrate as mentioned above.

The In addition, the liquid crystal display device also includes other components if needed.

Specific examples of the liquid crystal display device basically include but are not limited to the following. (1) The aforementioned TFT array substrate (driver substrate) and a color filter (CF) substrate are disposed oppositely, spacers are disposed therebetween for forming a space, and LC material is sealed in the space, so as to assemble the LCD device. In such case, the TFT array substrate has driving components (including TFTs) and pixel electrodes (electrically conductive layer) arranged thereon, and the CF substrate is constituted by CF and a counter electrode (electrically conductive layer). Alternatively, (2) the aforementioned TFT array substrate is combined with the CF substrate for forming a one-piece CF-TFT array substrate, and the one-piece CF-TFT array substrate and a counter substrate with the counter electrode (electrically conductive layer) are disposed oppositely, spacers are disposed therebetween for forming a space, and the LC material is sealed in the space, so as to assemble the LCD device. The LC material can be any prior LC compound or composition without any limitation.

Specific examples of the aforementioned electrically conductive layer include but are not limited to indium tin oxide (ITO) film; a metal film such as aluminum, zinc, copper, iron, nickel, chromium, molybdenum or the like; and metal oxide film such as silicon dioxide or the like. Among those films, a transparent film is preferred, and the ITO film more preferred.

Specific examples of the aforementioned substrate used in the TFT array substrate, the CF substrate and the counter substrate include but are not limited to the prior glass such as Na—Ca glass, low-swelling glass, alkali-free glass, a quartz glass or the like. In addition, the aforementioned substrate may include a plastic substrate.

The following examples are given for the purpose of illustration only and are not intended to limit the scope of the present invention.

### EXAMPLE

### Synthesis Example 1

### Method of Synthesizing High-Ortho Novolac Resin (A-1-1)

A 1000 mL four-necked conical flask equipped with a nitrogen inlet, a stirrer, a heater, a condenser and a thermometer was purged with nitrogen, and the components were charged to the flask. The aforementioned components comprising 64.89 g (0.6 mole) of m-cresol, 43.26 g (0.4 mole) of p-cresol, 0.5 g (0.0028 mole) of manganese acetate and 48.70 g (0.6 mole) of 37 wt % formaldehyde solution were stirred slowly to polymerize for 3 hours. Next, 1.38 g (0.01 mole) of salicylic acid was added and the pH was adjusted to pH 3.5, followed by dehydration under a decreased pressure at 300 mmHg for 30 minutes. After the reaction was completed, the reaction solution was slowly heated to 150° C. for evaporating the solvent, thereby obtaining a high-ortho novolac resin (A-1-1).

The methylene binding number of the resulted high-ortho novolac resin (A-1-1) was determined by carbon-13 nuclear magnetic resonance (¹³C-NMR) spectrometry, and the ratio of ortho-ortho methylene bonding to all methylene bonding was 18% calculated by the following method.

### Synthesis Example 2

### Method of Synthesizing High-Ortho Novolac Resin (A-1-2)

A 1000 mL four-necked conical flask equipped with a nitrogen inlet, a stirrer, a heater, a condenser and a thermometer was purged with nitrogen, and the components were charged to the flask. The aforementioned components comprising 64.89 g (0.6 mole) of m-cresol, 43.26 g (0.4 mole) of p-cresol, 0.5 g (0.0028 mole) of manganese acetate and 56.82 g (0.7 mole) of 37 wt % formaldehyde solution were stirred slowly to polymerize for 3 hours. Next, 0.37 g (0.003 mole) of benzoic acid was added and the pH was adjusted to pH 4.8, followed by dehydration under reduced pressure at 300 mmHg for 30 minutes. After the reaction was completed, 0.03 g (0.0002 mol) of dimethyl sulfate was added and the reaction solution was slowly heated to 150° C. for evaporating the solvent, thereby obtaining a high-ortho novolac resin (A-1-2).

The methylene binding number of the resulted high-ortho novolac resin (A-1-2) was determined by carbon-13 nuclear magnetic resonance (¹³C-NMR) spectrometry, and the ratio of ortho-ortho methylene bonding to all methylene bonding was 25% calculated by the following method.

### Synthesis Example 3

### Method of Synthesizing Novolac Resin (A-2-1)

A 1000 mL four-necked conical flask equipped with a nitrogen inlet, a stirrer, a heater, a condenser and a thermometer was purged with nitrogen, and the components were charged to the flask. The aforementioned components comprising 64.89 g (0.6 mole) of m-cresol, 43.26 g (0.4 mole) of p-cresol, 1.8 g (0.02 mole) of oxalic acid and 48.70 g (0.6 mole) of 37 wt % formaldehyde solution were stirred slowly to polymerize for 3 hours. Next, the reaction solution was slowly heated to 150° C. for evaporating the solvent, thereby obtaining a high-ortho novolac resin (A-2-1).

The methylene binding number of the resulted high-ortho novolac resin (A-2-1) was determined by carbon-13 nuclear magnetic resonance (¹³C-NMR) spectrometry, and the ratio of ortho-ortho methylene bonding to all methylene bonding was 16% calculated by the following method.

### Synthesis Example 4

### Method of Synthesizing Novolac Resin (A-2-2)

A 1000 mL four-necked conical flask equipped with a nitrogen inlet, a stirrer, a heater, a condenser and a thermometer was purged with nitrogen, and the components were charged to the flask. The aforementioned components comprising 64.89 g (0.6 mole) of m-cresol, 32.45 g (0.3 mole) of p-cresol, 12.22 g (0.1 mol) 2,5-dimethylphenol, 0.9 g (0.01 mole) of oxalic acid and 44.64 g (0.55 mol) of 37 wt % formaldehyde solution were stirred slowly to polymerize for 3 hours. Next, the reaction solution was slowly heated to 150° C. for evaporating the solvent, thereby obtaining a high-ortho novolac resin (A-2-2).

The methylene binding number of the resulted high-ortho novolac resin (A-2-2) was determined by carbon-13 nuclear magnetic resonance (¹³C-NMR) spectrometry, and the ratio of ortho-ortho methylene bonding to all methylene bonding was 14% calculated by the following method.

### Synthesis Example 5

### Method of Synthesizing Novolac Resin (A-2-3)

A 1000 mL four-necked conical flask equipped with a nitrogen inlet, a stirrer, a heater, a condenser and a thermometer was purged with nitrogen, and the components were charged to the flask. The aforementioned components comprising 64.89 g (0.6 mole) of m-cresol, 32.45 g (0.3 mole) of p-cresol, 12.22 g (0.1 mol) 2,5-dimethylphenol, 0.72 g (0.008 mole) of oxalic acid and 44.64 g (0.55 mol) of 37 wt % formaldehyde solution were stirred slowly to polymerize for 3 hours. Next, the reaction solution was slowly heated to 150° C. for evaporating the solvent, thereby obtaining a high-ortho novolac resin (A-2-3).

The methylene binding number of the resulted high-ortho novolac resin (A-2-3) was determined by carbon-13 nuclear magnetic resonance (¹³C-NMR) spectrometry, and the ratio of ortho-ortho methylene bonding to all methylene bonding was 13% calculated by the following method.

### Method of Manufacturing Positive Photosensitive Resin Composition

The following examples are directed to the preparation of the positive photosensitive resin composition of Examples 1 to 9 and Comparative Examples 1 to 5 according to Table 1.

### Example 1

100 parts by weight of the high-ortho novolac resin (A-2-1), 20 parts by weight of the ester of 2,3,4-trihydroxybenzophenone and 1,2-naphthoquinone diazide-5-sulfonic acid (B-1) and 5 parts by weight of the ester of 2,3,4,4′-tetrahydroxybenzophenone and 1,2-naphthoquinone diazide-5-sulfonic acid (B-2), 10 parts by weight of C.I. Solvent Black 34 (trade name of VALIFAST Black 3804; made by ORIENT CHEMICAL.) (C-1-2), 5 parts by weight of C.I. Acid Violet 17 (trade name of Coomassie Violet R200; made by Sigma) (C-2-1) were added into 800 parts by weight of propylene glycol monomethyl ether acetate (PGMEA; D-1), all of which were stirred and mixed well in a shaking mixer, so as to form a positive photosensitive resin composition of Example 1.

And then, the temporal stability of the positive photosensitive resin composition, the resolution and the residual film ratio of the pattern formed by the positive photosensitive resin composition were determined by using the following evaluation methods and resulted in Table 1.

### Examples 2 to 9

Examples 2 to 9 were prepared with the same method as in Example 1 by using various kinds or usage of the components listed in Table 1.

### Comparative Examples 1 to 5

Comparative Examples 1 to 5 were prepared with the same method as in Example 1 by using various kinds or usage of the components listed in Table 1.

TABLE 1

| | | Examples | | | | | | | | | Comparative examples | | | | |
|---|---|---|---|---|---|---|---|---|---|---|---|---|---|---|---|
| Component | | 1 | 2 | 3 | 4 | 5 | 6 | 7 | 8 | 9 | 1 | 2 | 3 | 4 | 5 |
| novolac resin (A) | A-1-1 | | | | | 30 | | | | | | | | | 30 |
| (parts by weight) | A-1-2 | | | | | | | | | 90 | | | | | |
| | A-2-1 | 100 | | | 100 | | 80 | | | | 100 | 100 | | | |
| | A-2-2 | | 100 | | | 70 | | 100 | 100 | | | | 100 | 100 | 70 |
| | A-2-3 | | | 100 | | | 20 | | | 10 | | | | | |
| ortho-naphthoquinone | B-1 | 20 | 25 | 20 | 18 | 20 | 25 | 20 | 35 | 20 | 20 | 20 | 20 | 25 | 20 |
| diazide sulfonic acid | B-2 | 5 | | 5 | 7 | | | 10 | 3 | 5 | 5 | 5 | 10 | | |
| ester (B) (parts by | | | | | | | | | | | | | | | |
| weight) | | | | | | | | | | | | | | | |
| dye(C) | C-1-1 | | 15 | 8 | | | | | 12 | | | | | | |
| (parts by weight) | C-1-2 | 10 | | | | | 6 | 2 | | 8 | | 10 | 2 | | |
| | C-1-3 | | | | 10 | 10 | | | | | | | | | |
| | C-2-1 | 5 | 5 | | | | | 8 | | 5 | 5 | | | | |
| | C-2-2 | | | 8 | | 3 | 10 | | | | | | | | 3 |
| | C-2-3 | | | | 6 | | | | 1 | | | | | | |
| | C-3-1 | | | | | 6 | | | | | | | | | |
| | C-3-2 | | | | | | | 15 | | | | | 15 | | |
| solvent(D) | D-1 | 800 | 750 | 750 | 550 | | 600 | 800 | | 1200 | 800 | 800 | 800 | 750 | |
| (parts by weight) | D-2 | | | | 150 | 400 | 100 | 50 | 750 | | | | 50 | | 400 |
| | D-3 | | | | | 400 | | | | | | | | | 400 |
| additives(E) | E-1 | | | 1 | | | 0.3 | | | | | | | | |
| (parts by weight) | E-2 | | | | | | 2 | | | 1 | | | | | |
| | E-3 | | | | 3 | | | | | | | | | | |
| assays | Temporal stability | ◯ | ◯ | ◯ | ◯ | ⊚ | ◯ | ⊚ | ◯ | ◯ | X | X | X | X | X |
| | of viscosity | | | | | | | | | | | | | | |
| | Temporal stability | ◯ | ◯ | ◯ | ◯ | ⊚ | ◯ | ◯ | ◯ | ⊚ | X | X | X | X | X |
| | of sensitivity | | | | | | | | | | | | | | |

A-1-1 a high-ortho novolac resin, prepared by m-cresol, p-cresol, manganese acetate and formaldehyde in a salicylic acid solvent; having 18% of ortho-ortho methylene bonding
A-1-2 a high-ortho novolac resin, prepared by m-cresol, p-cresol, manganese acetate and formaldehyde in a benzoic acid solvent; having 25% of ortho-ortho methylene bonding
A-2-1 a novolac resin, prepared by m-cresol, p-cresol, oxalic acid and formaldehyde; having 16% of ortho-ortho methylene bonding
A-2-2 a novolac resin, prepared by m-cresol, p-cresol, 2,5-dimethylphenol, oxalic acid and formaldehyde; having 14% of ortho-ortho methylene bonding
A-2-3 a novolac resin, prepared by m-cresol, p-cresol, 2,5-dimethylphenol, oxalic acid and formaldehyde; having 13% of ortho-ortho methylene bonding
B-1 ester of 2,3,4-trihydroxybenzophenone and 1,2-naphthoquinone diazide-5-sulfonic acid
B-2 ester of 2,3,4,4′-tetrahydroxybenzophenone and 1,2-naphthoquinone diazide-5-sulfonic acid
C-1-1 C.I. Solvent Black 3 (trade name of Sudan Black 141; manufactured by Chuo synthetic Chemical Co)
C-1-2 C.I. Solvent Black 34 (trade name of VALIFAST Black 3804; manufactured by ORIENT CHEMICAL)
C-1-3 C.I. Solvent Black 27 (trade name of Neozapon Black X51; manufactured by BASF)
C-2-1 C.I. Acid Violet 17 (trade name of Coomassie Violet R200; manufactured by Sigma)
C-2-2 C.I. Basic Blue 7 (trade name of Basonyl Blau 636; manufactured by BASF)
C-2-3 C.I. Acid Blue 83 (trade name of Brilliant Blue R; manufactured by Trust Chem)
C-3-1 C.I. Direct Blue 86 (trade name of Turquoise Blue; manufactured by Italia Incorporation)
C-3-2 C.I. Solvent Blue 70 (trade name of Neozapon Blue 807; manufactured by BASF)
D-1 PGMEA, propylene glycol monomethyl ether acetate
D-2 EL, ethyl lactate
D-3 PGEE, propylene glycol monoethyl ether
E-1 Surfactant; trade name of SF8427; manufactured by Toray Dow Corning Silicone
E-2 Adhesiveness imptover; trade name of Cymel-303; manufactured by CYTEC
E-3 Sensitizer; trade name of TPPA-MF; manufactured by Honsyu Chenical Industry Ltd., JP

### Assays

### Temporal Stability of Sensitivity

The positive photosensitive resin composition of Examples 1 to 9 and Comparative examples 1 to 5 were spin-coated on a 6-inch wafer, the composition was pre-baked at 120° C. for 2 minutes with a heating plate to obtain an 1 μm of pre-baked coating film. The pre-backed coating film was subjected to a line and space mask (Japan Filcon system, 1L/1S), and irradiated with different energy ultraviolet irradiation (Exposure Model AG500-4N; M & R Nano Technology system), and then developed for 1 minute at 23° C. with 2.38% of tetramethylammonium hydroxide solution. The exposed parts of the coating film on the substrate was removed, and then washed with pure water. The exposure time (optimal exposure time) Eop1 of forming the 1:1 line can be obtained.

Furthermore, the positive photosensitive resin composition of Examples 1 to 9 and Comparative examples 1 to 5 were stayed at 23° C. or 7 days. The optimal exposure time Eop2 was obtained according to the same process. ΔEop can be obtained according to the following formula and the temporal stability of sensitivity was evaluated.

ΔEop(mJ/cm²)=Eop2−Eop1

⊚: ΔEop<30

◯: 50>ΔEop≧30

x: ΔEop≧50

### Temporal Stability of Viscosity

The positive photosensitive resin composition of Examples 1 to 9 and Comparative examples 1 to 5 were heated in an oven at 45° C. for one month. The viscosity before heating treatment was designed as μ₀, and the viscosity after heating treatment was designed as μ₁. The viscosity changing ratio was obtained according to the following formula, and the temporal stability was assayed.

viscosity changing ratio=μ₀−μ₁/μ₀×100%

μ₀: viscosity before heating treatment

μ₁: viscosity after heating treatment

◯: viscosity changing ratio<5%

X: viscosity changing ratio 5%

The results were shown in Table 1. It is shown that using the novolac resin (A-2) along with the dye (C-1) and dye (C-2), the temporal stability of viscosity and sensitivity is good (◯); using the high-ortho novolac resin (A-1) along with the dye (C-1) and dye (C-2), the temporal stability of sensitivity is excellent (⊚); using the novolac resin (A-2) along with the dye (C-1), dye (C-2) and dye (C-3), the temporal stability of viscosity is excellent (⊚); using the high-ortho novolac resin (A-1) along with the dye (C-1), dye (C-2) and dye (C-3), the temporal stability of viscosity and sensitivity is excellent (⊚).

In the Comparative examples, without using the dye (C-1) and dye (C-2) at the same time, without using the dye (C), using the dye (C-1) or the dye (C-2) with the high-ortho novolac resin (A-1), the temporal stability of viscosity and sensitivity is poor (x).

### Evaluation of Ratio of Ortho-Ortho Methylene Bonding to all Methylene Bonding

The methylene binding number of the resulted novolac resin (A) was determined by ¹³C-NMR spectrometer (AV400, Bruker). And then, the ratios of ortho-ortho methylene bonding to all methylene bonding of Synthesis Examples 1-5 were calculated according to the following equation.

$$Ratio ( \% ) of Ortho \text{-} Ortho Methylene Bonding to All Methylene Bonding = \frac{( ortho \text{-} ortho bonding )}{\begin{matrix}( ortho \text{-} ortho bonding ) + \\ ( ortho \text{-} para bonding ) + ( para \text{-} para bonding )\end{matrix}} \times 100 \qquad ( III )$$

In the equation, the ortho-ortho bonding is referred to the number of methylene bonding at the ortho-ortho position, the ortho-para bonding is referred to the number of methylene bonding at the ortho-para position, and the para-para bonding is referred to the number of methylene bonding at the para-para position.

While embodiments of the present invention have been illustrated and described, various modifications and improvements can be made by persons skilled in the art. It is intended that the present invention is not limited to the particular forms as illustrated, and that all modifications not departing from the spirit and scope of the present invention are within the scope as defined in the following claims.

What is claimed is:

1. A positive photosensitive resin composition comprising:
a novolac resin (A);
an ortho-naphthoquinone diazide sulfonic acid ester (B);
a dye (C); and
a solvent (D);
wherein the dye comprises a dye (C-1) and a dye (C-2), and the dye (C-1) is selected from the group consisting of a disazo dye, an anthraquinone dye, and a trivalent chromium azo dye; and the dye (C-2) is a triarylmethane dye.

2. The positive photosensitive resin composition according to claim 1, wherein the novolac resin (A) includes a high-ortho novolac resin (A-1) that has 18% to 25% of ortho-ortho methylene bonding.

3. The positive photosensitive resin composition according to claim 1, wherein the dye (C-2) has a structure represented by the following general formula (1) or formula (2) or a salt thereof, 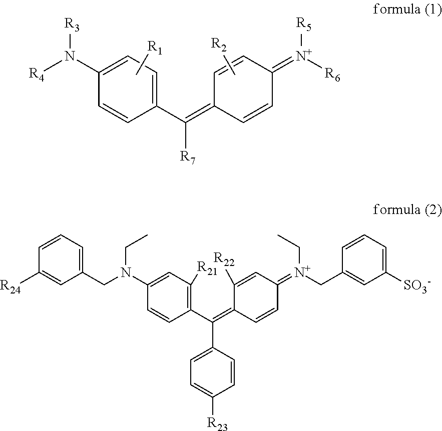
wherein in formula (1),
R₁ and R₂ are independently selected from the group consisting of a hydrogen atom, a halogen atom and a C₁ to C₅ alkyl group;
R₃, R₄, R₅, and R₆ are independently selected from the group consisting of a hydrogen atom, a C₁ to C₅ alkyl group, a phenyl group and a benzyl group; and
R₇ is selected from the group consisting of the general formula (3), formula (4) and formula (5), 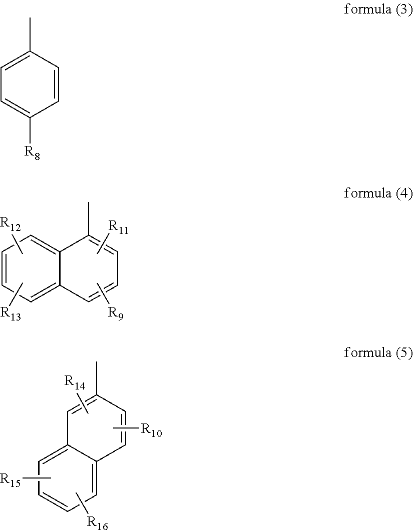
wherein:
R₈ to R₁₀ are selected from the group consisting of a hydrogen atom and —NR₂₅R₂₆;
wherein:
R₂₅ and R₂₆ are independently selected from the group consisting of a hydrogen atom, a C₁ to C₅ alkyl group, a benzyl group, a phenyl group, and a phenyl group substituted by a C₁ to C₃ alkoxy group or by a C₁ to C₃ alkyl group in the para position; and
R₁₁ to R₁₆ are independently selected from the group consisting of a hydrogen atom, a hydroxyl group and —SO³⁻;
wherein in formula (2),
R₂₁ and R₂₂ are independently selected from the group consisting of a hydrogen atom, a halogen atom, and a C₁ to C₅ alkyl group; and
R₂₃ is selected from the group consisting of a hydrogen atom, —SO³⁻, a carboxyl group, a C₁ to C₃ alkyl group, a C₁ to C₅ alkoxyl group, and —NR₂₅R₂₆; and
R₂₄ is selected from the group consisting of a hydrogen atom and —SO³⁻.

4. The positive photosensitive resin composition according to claim 1, wherein the amount of the dye (C) used is from 10 to 35 parts by weight based on 100 parts by weight of the novolac resin (A) used.

5. The positive photosensitive resin composition according to claim 1, wherein the amount of the dye (C-1) used is from 2 to 15 parts by weight, and the amount of the dye (C-2) used is from 1 to 10 parts by weight based on 100 parts by weight of the novolac resin (A) used.

6. The positive photosensitive resin composition according to claim 1, wherein the dye (C) further comprises a dye (C-3), and the dye (C-3) is a phthalocyanine dye.

7. The positive photosensitive resin composition according to claim 6, wherein the amount of the dye (C-3) used is from 5 to 30 parts by weight based on 100 parts by weight of the novolac resin (A) used.

8. A method for manufacturing a thin-film transistor array substrate, wherein the thin-film transistor array substrate comprises a substrate and a pattern, the method comprising coating the positive photosensitive resin composition according to claim 1 on the substrate to form the pattern.

9. The method according to claim 8, wherein the novolac resin (A) includes a high-ortho novolac resin (A-1) that has 18% to 25% of ortho-ortho methylene bonding.

10. The method according to claim 8, wherein the dye (C-2) has a structure represented by the following general formula (1) or formula (2) or a salt thereof, 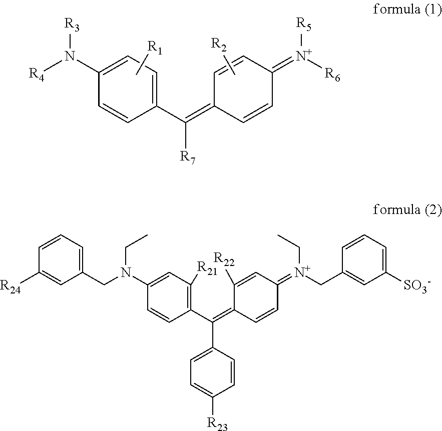
wherein in formula (1),
R₁ and R₂ are independently selected from the group consisting of a hydrogen atom, a halogen atom and a C₁ to C₅ alkyl group;
R₃, R₄, R₅, and R₆ are independently selected from the group consisting of a hydrogen atom, a C₁ to C₅ alkyl group, a phenyl group and a benzyl group; and
R₇ is selected from the group consisting of the general formula (3), formula (4) and formula (5), 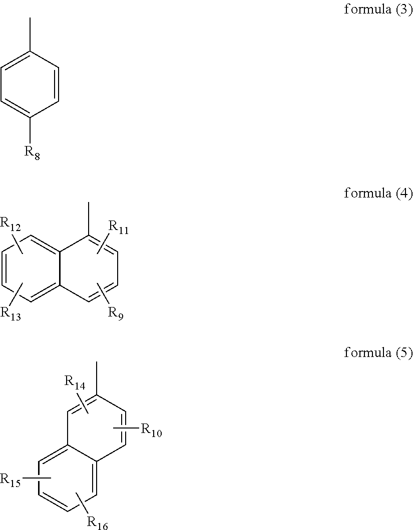
wherein:
R₈ to R₁₀ are selected from the group consisting of a hydrogen atom and —NR₂₅R₂₆;
wherein:
R₂₅ and R₂₆ are independently selected from the group consisting of a hydrogen atom, a C₁ to C₅ alkyl group, a benzyl group, a phenyl group, and a phenyl group substituted by a C₁ to C₃ alkoxy group or by a C₁ to C₃ alkyl group in the para position; and
R₁₁ to R₁₆ are independently selected from the group consisting of a hydrogen atom, a hydroxyl group and —SO³⁻;
wherein in formula (2),
R₂₁ and R₂₂ are independently selected from the group consisting of a hydrogen atom, a halogen atom, and a C₁ to C₅ alkyl group; and
R₂₃ is selected from the group consisting of a hydrogen atom, —SO³⁻, a carboxyl group, a C₁ to C₃ alkyl group, a C₁ to C₅ alkoxyl group, and —NR₂₅R₂₆; and
R₂₄ is selected from the group consisting of a hydrogen atom and —SO³⁻.

11. The method according to claim 8, wherein the amount of the dye (C) used is from 10 to 35 parts by weight based on 100 parts by weight of the novolac resin (A) used.

12. The method according to claim 8, wherein the amount of the dye (C-1) used is from 2 to 15 parts by weight, and the amount of the dye (C-2) used is from 1 to 10 parts by weight based on 100 parts by weight of the novolac resin (A) used.

13. The method according to claim 8, wherein the dye (C) further comprises a dye (C-3), and the dye (C-3) is a phthalocyanine dye.

14. The method according to claim 8, wherein the amount of the dye (C-3) used is from 5 to 30 parts by weight based on 100 parts by weight of the novolac resin (A) used.

15. A thin-film transistor array substrate manufactured according to the method according to claim 8.

16. A liquid crystal display device comprising the thin-film transistor array substrate according to claim 9.
